(19) United States
(12) Patent Application Publication
(10) Pub. No.: US 2008/0211491 A1
(43) Pub. Date: Sep. 4, 2008

(54) HIGH SENSITIVITY, PASSIVE MAGNETIC FIELD SENSOR AND METHOD OF MANUFACTURE

(75) Inventors: Jiankang Huang, Roslindale, MA (US); Robert C. O'handley, Andover, MA (US)

Correspondence Address: RISSMAN JOBSE HENDRICKS & OLIVERIO, LLP, 100 Cambridge Street, Suite 2101, BOSTON, MA, 02114, US

(73) Assignee: Ferro Solutions, Inc., Roslindale, MA (US)

(21) Appl. No.: 11/840,459

(22) Filed: Aug. 17, 2007

Related U.S. Application Data
(63) Continuation of application No. 10/730,355, filed on Dec. 8, 2003, now abandoned.
(60) Provisional application No. 60/431,487, filed on Dec. 9, 2002.

(51) Int. Cl. G01R 33/18

(52) U.S. Cl. 324/209

(57) ABSTRACT

A magnetic field sensor comprises one or more magnetic layers of magnetostrictive material that is mechanically bonded to one or more layers of electroactive material. When a magnetic field is applied to the device, it rotates the magnetization that is present in the in the magnetostrictive material thereby generating a magnetostrictive stress in the material. The magnetostrictive stress generated by this layer, in turn, stresses the piezoelectric layer to which the magnetostrictive layer is bonded. In order to increase sensitivity, the voltage across the piezoelectric material is measured in a direction that is parallel to the plane in which the magnetization in the magnetic material rotates.

### RELATED APPLICATIONS

This application claims the benefit of U.S. Provisional Application No. 60/431,487, filed Dec. 9, 2002.

### FIELD OF THE INVENTION

This invention relates to magnetic field sensors, and specifically to solid-state magnetic field sensors that generate a voltage in response to an applied magnetic field by means of a magnetostrictive layer bonded to an electroactive layer.

### BACKGROUND OF THE INVENTION

There are a variety of conventional devices for measuring magnetic field strength. These known devices include inductive pickup coils, Hall Effect probes, flux gate magnetometers, and magnetostrictive sensors. The latter class of sensors includes passive solid-state devices that comprise one or more magnetic layers of magnetostrictive material that are mechanically bonded to one or more layers of piezoelectric material. When a magnetic field is applied to the device, it rotates the magnetization that is present in the in the magnetostrictive material thereby generating a magnetostrictive stress in the material. The magnetostrictive stress generated by this layer, in turn, stresses the piezoelectric layer to which the magnetostrictive layer is bonded. In response, the stressed piezoelectric layer generates a voltage that can be measured across two electrodes attached to the piezoelectric layer. These devices have applications in passive field sensing, in detection of remote magnetic objects, in navigation, in measuring or control of rotating machinery, measurement or control of fluid flow, magnetic data reading, security tags, card readers and magnetometers.

Embodiments of the basic prior art device are illustrated in FIGS. 1, 2 and 3. The prior art device 100 shown in block schematic form in FIG. 1 is a fully passive device that requires no input power to detect a magnetic field change. It comprises two or more magnetostrictive layers 104 and 110 that are mechanically bonded by conductive epoxy glue, or other means, to a piezoelectric layer 108. Metallic electrodes 102 and 112 may be applied to the two magnetostrictive layers 104 and 110, respectively, or the magnetostrictive layers themselves (if they are metallic) may serve as the electrodes. The magnetostrictive layers 104 and 100 have a quiescent magnetization vector 115 (M) which orients itself to minimize the number of magnetic poles appearing on the surface of the magnetostrictive material. In a layer with a rectangular shape, such as layers 104 and 110, the magnetic vector M may be oriented, on average, parallel with the longest side of the rectangle as shown in FIG. 1. The magnetic layer also may be annealed in a transverse magnetic field so that the quiescent magnetization vector is oriented along the width of the device. An external magnetic field (H) applied in a direction (schematically indicated by arrow 114) transverse to the quiescent magnetization vector causes a rotation of the magnetization vector M into the direction of the applied field H. This rotation produces a stress in the magnetostrictive layers 104 and 110. The stress is maximized when the external magnetic field H, applied at a 90° angle to the quiescent magnetization vector M, is strong enough to rotate the magnetization into the field direction.

The sensor shown in FIG. 1 operates in a “d₃₁ mode” in which the principal stress generated by the rotating magnetization is orthogonal to the electric field vector generated by the piezoelectric material 108 and represented by arrows 106. Thus, the applied magnetic field rotates the magnetization vectors of layers 102 and 112 in the plane of electrodes 102 and 112 whereas the voltage generated by the piezoelectric material 108 is measured in a direction that is normal to the plane of electrodes 102 and 112. The magnitude of the voltage developed across electrodes 102 and 112 is a function of the magnetic field strength, the magnetoelastic coupling constant of the magnetic material, the relative thickness of the magnetic and electroactive layers and the distance (d) between the electrodes 102 and 112. This voltage can be detected by a device 118 that is connected to electrodes 102 and 112 by conductors 116 and 120. Such a magnetostrictive sensor is described in detail in an article titled “An innovative, passive, solid-state, magnetic field sensor”, Y-Q. Li and R. C. O'Handley, Journal of Applied Sensing Technology, v. 17, p. 10 (2000) and in U.S. Pat. No. 6,279,406, Aug. 28, 2001.

Another prior art device is shown in FIG. 2. This device is an “active” device because it uses a small AC bias magnetic field to increase sensitivity. The device comprises a single magnetostrictive layer 204 bonded to a piezoelectric layer 208. The AC bias magnetic field is applied to the magnetic layer 204 by a coil 210. This device also operates in a “d₃₁ mode” in which the external magnetic field H is applied in a direction (for example, indicated by arrow 212) to rotate the magnetization in a plane that is orthogonal to the electric field vector represented by arrows 206. The magnetization vector 211 (M) of the magnetostrictive layer 204 rotates in the plane of electrodes 202 and 209. As with the previous prior art sensor, the magnitude of the voltage developed across electrodes 202 and 209 is a function of the magnetic field strength and the distance (d) between the electrodes 202 and 209 and can be detected by a device 216 that is connected to electrodes 202 and 209 by conductors 214 and 218. Such a magnetostrictive sensor is described in detail in an article titled “A New Magnetic Sensor Technology”, B. J. Lynch and H. R. Gallantree, GEC Journal of Research, v. 8 n. 1 (1990).

In both of these prior art sensors, the magnetization is rotated in the plane of the magnetic layer because rotating the magnetization in a direction perpendicular to the layer generally requires a larger external field. However, magnetization rotation in the plane of the magnetic layer does not generate a large voltage in the piezoelectric element in the direction normal to the magnetic layers. In particular, the coupling between the magnetic stress applied to the piezoelectric element and the voltage produced across the piezoelectric element is governed by a piezoelectric coupling factor g₃₁=g₁₃ that typically has a value on the order of 0.011 Volts/(meter-Pa) in commercially available piezoelectric materials. With this coupling factor, a device such as that shown in FIG. 1 has a magnetic field sensitivity typically on the order of 280 nanovolts/nanotesla (nV/nT). A device such as that shown in FIG. 2 has a magnetic field sensitivity typically on the order of 1200 nV/nT. These magnetic field sensitivities limit the applications in which the devices can be used. In addition, the device shown in FIG. 2 requires power to generate the AC bias field and thus is further limited in its application.

The rectangular shape of the magnetic field sensors illustrated in FIGS. 1 and 2 introduces a shape anisotropy in the plane in which the magnetization vector rotates. One prior art sensor has circular symmetry and, the external field is applied normal to the thin, circular disk-shaped layers. Such a prior art sensor 300 is illustrated in FIG. 3 and comprises two disk-shaped magnetostrictive layers 302 and 306 bonded to a disk-shaped piezoelectric layer 304. Electrodes 308 and 310 are applied to the circular faces of the piezoelectric layer as shown. The resulting voltage can be measured across the electrodes 308, 310 by a device 316, via electrical connections 312 and 314. An external field is applied in the direction schematically indicated by arrow 318. A field applied in this direction is less effective in rotating the magnetization than a field applied in the plane of the sample because perpendicular magnetization requires a field that also must overcome magnetostatic energy. This device will not be as sensitive to weak fields as the first two prior art devices described above. Such a device is described in detail in an article titled “Magnetoelectric Properties in Piezoelectric and Magnetostrictive Laminate Composites”, R. Jungho, A. Vazquez, K. Uchino and H. Kim, Japan Journal of Applied Physics, v. 40 (1), n. 8, pp. 4948-4951 (2001).

### SUMMARY OF THE INVENTION

In accordance with the principles of the invention a passive magnetostrictive sensor is constructed so that the voltage or electric field that is produced in the piezoelectric element in the presence of an applied magnetic field is much larger than the voltage produced in prior art devices in response to the same applied magnetic field. In particular, the voltage across the piezoelectric material is measured in a direction that is parallel to the plane in which the magnetization in the magnetic material rotates. With this configuration, the magnitude of the voltage developed by the piezoelectric material is governed by the piezoelectric coupling coefficients d₃₃ or g₃₃, which are typically 3 to 10 times larger than the d₃₁, d₁₃, g₃₁ or g₁₃ coefficients that govern the magnitude of the generated voltage in the prior art devices 1 and 2. The magnetization rotation in the inventive device described below is fully in the thin plane of the magnetostrictive layer(s), unlike the prior art device of FIG. 3.

In another embodiment, the piezoelectric material is replaced with another electroactive material, such as an electrostrictive material (for example, (Bi_{0.5}Na_{0.5})₁₋ₓBaₓZr_{y}Ti_{1-y}O₃), a relaxor ferroelectric material (for example, Pb(Mg_{1/3}Nb_{2/3})₃) or an electroactive polymer (for example, polyvinyledine difluoride, PVDF).

### BRIEF DESCRIPTION OF THE DRAWINGS

The above and further advantages of the invention may be better understood by referring to the following description in conjunction with the accompanying drawings in which:

FIG. 1 is a block schematic diagram of a prior art magnetostrictive magnetic field sensor.

FIG. 2 is a block schematic diagram of another prior art magnetostrictive magnetic field sensor.

FIG. 3 is a block schematic diagram of a further prior art magnetostrictive magnetic field sensor.

FIG. 4 is a block schematic diagram of a magnetostrictive magnetic field sensor constructed in accordance with the principles of the present invention.

FIG. 5 is a block schematic diagram of another embodiment of a magnetostrictive magnetic field sensor constructed in accordance with the principles of the present invention with two magnetostrictive layers bonded to faces of the electroactive layer.

FIG. 6 is a block schematic diagram of another embodiment of a magnetostrictive magnetic field sensor constructed in accordance with the principles of the present invention in which the two magnetostrictive layers are bonded to electroactive layer faces that differ from those in the embodiment shown in FIG. 5.

FIG. 7 is a block schematic diagram of another embodiment of a magnetostrictive magnetic field sensor constructed in accordance with the principles of the present invention in which the electrodes are located on electroactive layer faces that differ from those in the embodiment shown in FIG. 5.

FIG. 8 is a block schematic diagram of another embodiment of a magnetostrictive magnetic field sensor constructed in accordance with the principles of the present invention in which the two magnetostrictive layers are bonded to electroactive layer faces that differ from those in the embodiment shown in FIG. 5 and the electrodes are located on electroactive layer faces that differ from those in the embodiment shown in FIG. 5.

FIG. 9 is a block schematic diagram of another embodiment of a magnetostrictive magnetic field sensor constructed in accordance with the principles of the present invention in which four magnetostrictive layers are bonded to electroactive layer faces.

FIG. 10 is a block schematic diagram of another embodiment of a magnetostrictive magnetic field sensor constructed in accordance with the principles of the present invention in which four magnetostrictive layers are bonded to electroactive layer faces that differ from those in the embodiment shown in FIG. 9 and the electrodes are located on electroactive layer faces that differ from those in the embodiment shown in FIG. 9.

FIG. 11 is a block schematic diagram of another embodiment of a magnetostrictive magnetic field sensor constructed in accordance with the principles of the present invention in which four magnetostrictive layers are bonded to electroactive layer faces that differ from those in the embodiment shown in FIGS. 9 and 10 and the electrodes are located on electroactive layer faces that differ from those in the embodiment shown in FIGS. 9 and 10.

FIG. 12 is a block schematic diagram of another embodiment of a magnetostrictive magnetic field sensor constructed in accordance with the principles of the present invention in which a single layer of magnetostrictive material is wrapped around, and bonded to, two opposing pairs of faces of the electroactive layer.

FIG. 13 is a block schematic diagram of another embodiment of a magnetostrictive magnetic field sensor constructed in accordance with the principles of the present invention in which a single layer of magnetostrictive material is wrapped around, and bonded to, two opposing pairs of faces of the electroactive layer, wherein the two opposing pairs of faces differ from those illustrated in FIG. 12.

FIG. 14 is a block schematic diagram of another embodiment of a magnetostrictive magnetic field sensor constructed in accordance with the principles of the present invention in which a single layer of magnetostrictive material is wrapped around, and bonded to, two opposing pairs of faces of the electroactive layer, wherein the two opposing pairs of faces differ from those illustrated in FIGS. 12 and 13.

FIG. 15 is a block schematic diagram of another embodiment of a magnetostrictive magnetic field sensor constructed in accordance with the principles of the present invention in which the electroactive layer is disk-shaped with an elliptical or circular cross-section.

FIG. 16 is a block schematic diagram of another embodiment of a magnetostrictive magnetic field sensor constructed in accordance with the principles of the present invention in which two disk-shaped magnetostrictive layers are bonded to a disk-shaped electroactive layer.

FIG. 17 is a block schematic diagram of another embodiment of a magnetostrictive magnetic field sensor constructed in accordance with the principles of the present invention in which two disk-shaped magnetostrictive layers are bonded to a cylindrical electroactive layer.

FIG. 18 is a block schematic diagram of another embodiment of a magnetostrictive magnetic field sensor constructed in accordance with the principles of the present invention in which a single magnetostrictive layer is wrapped around and bonded to a cylindrical electroactive layer.

FIG. 19 is a block schematic diagram of another embodiment of a magnetostrictive magnetic field sensor constructed in accordance with the principles of the present invention in which a single magnetostrictive layer is wrapped around and bonded to a hollow cylindrical electroactive layer and the electrodes are on the ends of the hollow cylindrical layer.

FIG. 20 is a block schematic diagram of another embodiment of a magnetostrictive magnetic field sensor constructed in accordance with the principles of the present invention in which a single magnetostrictive layer is wrapped around and bonded to a hollow cylindrical electroactive layer and the electrodes are on the inner and outer surface the hollow cylindrical layer.

FIG. 21 is a graph illustrating the output voltage versus the applied magnetic field strength for several sensor designs including designs constructed in accordance with the principles of the invention.

FIG. 22 is a flowchart showing the steps in an illustrative process for constructing a sensor in accordance with the principles of the invention.

### DETAILED DESCRIPTION

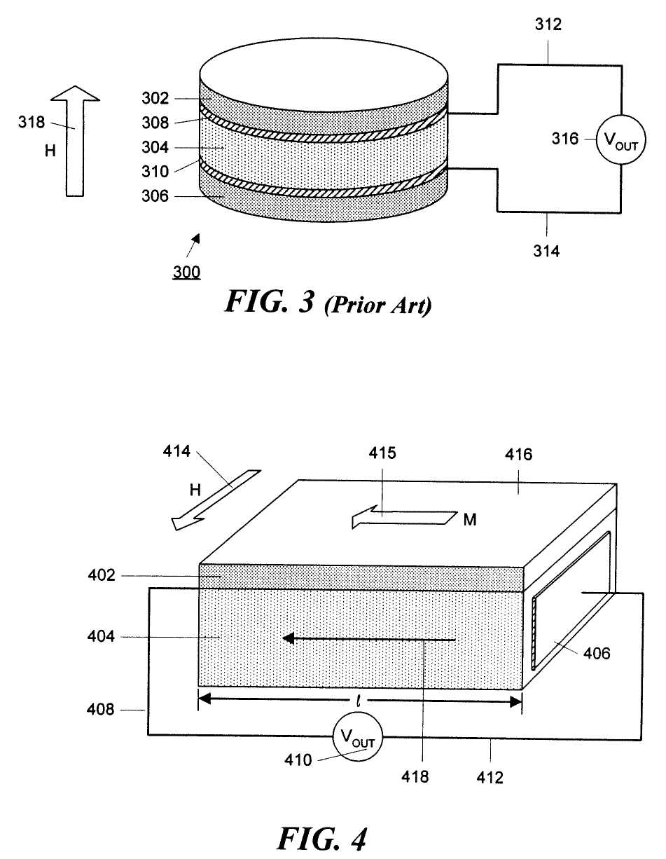

FIG. 4 is a block schematic diagram of an embodiment of a passive magnetostrictive sensor constructed in accordance with the principles of the invention. The sensor 400 comprises a magnetic layer 402 that is bonded to a piezoelectric layer 404 by a suitable non-conductive means, such as non-conductive epoxy glue. Although only one magnetic layer 402 is shown bonded to a single piezoelectric layer 404, those skilled in the art would understand that two or more magnetic layers can be used without departing from the spirit and scope of the invention. The magnetization vector 415 (M) of the magnetic material 402 rotates in the plane 416 of the magnetic layer 402 when an external magnetic field (H) is applied as shown by the arrow 414. The rotation of the magnetization vector M causes a stress in the magnetostrictive layer 402 which is, in turn, applied to the piezoelectric layer 404 to which the magnetic layer 402 is bonded. It is key to this design that the direction of magnetization, M, rotates in the preferred plane of magnetization, changing direction from being parallel to perpendicular (or vice versa) to a line joining the electrodes. This maximizes the stress change transferred to the electroactive element. It should be noted that the quiescent magnetization vector and the applied field directions could by orthogonal to the directions illustrated in FIG. 3.

The stress-induced voltage in the piezoelectric material 404 is measured across a pair of electrodes 406 and 407 of which only electrode 406 is shown in FIG. 4. The magnitude of the voltage developed across electrodes 406 and 407 is a function of the magnetic field strength for H<Hₐ, the anisotropy field (at which M is parallel to the applied field) and can be detected by a device 410 that is connected to electrodes 406 and 407 by conductors 412 and 408, respectively.

In accordance with the principles of the invention, the sensor is constructed so that stress-induced voltage is measured in a direction that is parallel to the plane 416 in which the magnetization rotates. The stress is generated in the magnetic material 402, which responds to an external magnetic field 414 (H) with a magnetoelastic stress, σ_{mag}, that has a value in the approximate range of 10 to 60 MPa. Because the magnetic material 402 is bonded to a piezoelectric layer 404, the layer 404 responds to the magnetostrictive stress with a voltage proportional to the stress, σ_{mag}, transmitted to it. Piezoelectric materials respond to a stress with a voltage, V, that is a function of the applied stress, a voltage-stress constant, gᵢⱼ, and the distance, l between the electrodes. In particular,

δV=gᵢⱼ^{piezo}fδσ_{mag}l

Here δσ_{mag} is the change in magnetic stress that is generated in the magnetic material by the field-induced change in its magnetization direction. A fraction, f, of this stress is transferred to the electroactive element. δV is the resulting stress-induced change in voltage across the electrodes on the electroactive element.

If the voltage is measured in a direction orthogonal to the direction in which the stress changes as is done in the prior art examples 1 and 2, then gᵢⱼ=g₁₃. As mentioned previously, typically piezoelectric values for g₁₃ are 10 millivolt/(meter-Pa). However, if the voltage is measured in a direction parallel to the direction in which the stress changes in accordance with the principles of the present invention, then gᵢⱼ=g₃₃. Thus, the sensor operates in a g₃₃ or d₃₃ mode. For a typical piezoelectric material g₃₃=24 millivolt/(meter-Pa)=0.024 volt-meter/Newton. In this case, a stress of 1 MPa generates an electric field of 24 kilovolt/meter. This field generates a voltage of 240 V across a 1 cm (l=0.01 m) wide piezoelectric layer.

The stress generated by the magnetic material 402 depends on the extent of rotation of its magnetization, a 90 degree rotation producing the full magnetoelastic stress. The extent of the rotation, in turn, depends of the angle between the magnetization vector 415 and the applied magnetic field direction 414 and also depends on the strength of the magnetic field. The fraction, f, of the magnetostrictive stress, σ_{mag}, transferred from magnetic to the piezoelectric layer depends on the (stiffness×thickness) product of the magnetic material, the effective mechanical impedance of the bond between the magnetic and electric elements (proportional to its stiffness/thickness), and the inverse of the (stiffness×thickness) of the piezoelectric layer

A quality factor may be defined from the above equation to indicate the sensitivity of the inventive device, that is, the voltage output per unit magnetic field, H (Volts-m/A):

$$\frac{\partial V}{\partial H} = {g}_{33}^{piezo} f ( \frac{\partial {σ}_{mag}}{\partial H} ) l$$

The characteristics of a suitable magnetostrictive material in this invention are large internal magnetic stress change as the magnetization direction is changed. This stress is governed by the magnetoelastic coupling coefficient, B₁, which, in an unconstrained sample, produces the magnetostrictive strain or magnetostriction, λ, proportional to B₁ and inversely proportional to the elastic modulus of the material. It is also important that the magnetization direction of the magnetic material can be rotated by a magnetic field of magnitude comparable to the fields of intended to be measured. In general, the magnetic material should also be mechanically robust, relatively stable (not prone to corrosion or decomposition), and receptive to adhesives. In addition, if the magnetic material is electrically non-conducting, it can be bonded to the electroactive element with the thinnest non-conducting adhesive layer that provides the needed strength without danger of shorting out the stress-induced voltage developed across the electroactive element. If the magnetostrictive layer is conducting, care must be taken that a non-conducting adhesive fully insulates it from the electroactive element.

Many known magnetostrictive materials can be used for the magnetic layer 402. These include various magnetic alloys, such as amorphous-FeBSi or Fe—Co—B—Si alloys, as well as crystalline nickel, iron-nickel alloys, or iron-cobalt alloys. For example, boro-silicate alloys of the form FeₓB_{y}Si_{1-x-y}, where 70<x<86 at %, 2<y<20, and 0<z=1−x−y<8 at % are suitable for use with the invention with a preferred composition near Fe₇₈B₂₀Si₂. Also suitable are alloys of the form FeₓCo_{y}B_{z}Si_{1-x-y-z} where 70<x+y<86 at % and y is between 1 and 46 at %, 2<z<18, and 0<1−x−y−z<16 at %, with a preferred composition near Fe₆₈Co₁₀B₁₈Si₄. Iron-nickel alloys with Ni between 40 and 70 at % with a preferred composition near 50% Ni can be used. Similarly, iron-cobalt alloys with Co between 30 and 80% and a preferred composition near 55% Co (such as Fe₅₀Co₅₀.) are also suitable.

Another magnetostrictive material that is also suitable for use with the invention is Terfenol-D® (TbₓDy₁₋ₓFe_{y}), an alloy of rare earth elements Dysprosium and Terbium with 3d transition metal Iron, manufactured by ETREMA Products, Inc., 2500 N. Loop Drive, Ames, Iowa 50010, among others. Terfenol-D® can generate a maximum stress of order 60 MPa for a 90-degree rotation of its magnetization. Such a rotation can be accomplished by an external applied magnetic field on the order of 400 to 1000 Oersteds (Oe). Also useful are new, highly magnetostrictive alloys such as Galfenol®, Fe₁₋ₓGaₓ. (an alloy currently under development by ETREMA Products). Softer magnetic materials, such as certain Fe-rich amorphous alloys mentioned above, may achieve full rotation of magnetization in fields of order 10 Oe, making them suitable for the magnetic layer in a sensor for sensing weaker fields. Finally, it is possible to use certain so-called nanocrystalline magnetic materials. In these polycrystalline materials, it is generally that case that the magnetization can be rotated as easily as it can be in amorphous materials. But nanocrystalline materials can sometimes be engineered to have larger magnetoelastic coupling coefficients than amorphous materials.

The characteristics of a suitable electroactive layer for the invented devices are primarily that they have a large stress-voltage coupling coefficient, g₃₃. In addition, they should be mechanically robust, receptive to adhesives, not degrade the metallic electrodes that must be placed on them (this is most often easily achieved when the electrodes are made of noble metals, such as silver or gold). Generally, the electroactive material is chosen on the basis of having a value of gᵢⱼ greater than 10 mV/(Pa-m).

The electroactive layer can be a ceramic piezoelectric material such as lead zirconate titanate Pb(ZrₓTi₁₋ₓ)O₃, or variations thereof, aluminum nitride (AIN) or simply quartz, SiOₓ. In some applications a single crystal (as opposed to a ceramic or polycrystalline) piezoelectric material may be advantageous. Alternatively, a polymeric piezoelectric material such as polyvinylidene difluoride (PVDF) would be suitable for applications of the invented devices where the stress transferred from the magnetostrictive material is relatively weak. The softness of the polymer will allow it to be strained significantly under weaker applied stress to produce a useful polarization, or voltage across its electrodes. It is also advantageous in some applications to use another electroactive material, such as an electrostrictive material (for example, (Bi_{0.5}Na_{0.5})₁₋ₓBaₓZr_{y}Ti_{1-y}O₃) or a relaxor ferroelectric material (for example, Pb(Mg_{1/3}Nb_{2/3})₃). Collectively, the piezoelectric, ferroelectric, electrostrictive and relaxor ferroelectric layers are called “electroactive” layers.

Piezoelectric materials typically have g₃₃˜4×g₉₃ and g₃₃≈20 to 30 mV/(Pa-m) which is about 10×d₃₁. For PVDF, g₃₃≈100 mV/(Pa-m) and some relaxor ferroelectrics can have g₂₂≈60 mv/(Pa-m).

The performance of the sensors of the present invention can be compared both theoretically and experimentally with those of the prior art. Sensors constructed in accordance with the principles of the present invention can show more than an order of magnitude gain relative to d₃₁ piezoelectric-based prior art sensors. This increased sensitivity comes from the two-fold to three-fold increase in g₃₃ relative to g₉₃ as well as from the increase in the distance between the electrodes. The sensitivity can also be further increased by replacing the piezoelectric element with a relaxor ferroelectric, for which g₃₃ typically has a magnitude 3×g₃₃ of a piezoelectric material.

Model predictions and experimental results shown in Table 1 below compare the performance of a sensor constructed in accordance with the principles of the present invention with that reported for the sensors of the prior art. In particular, Table 1 compares the parameters gᵢⱼ, in mV/m-Pa, the electrode spacing l in meters, the maximum stress per unit field (B₁/μₒHₐ) in Pa/T, and calculated field sensitivity in nV/nT and the observed field sensitivity, dV/dB. The values tabulated for a g₃₃ device using a relaxor ferroelectric are based on the data observed with a piezoelectric based sensor and using a ratio of g₃₃ for typical relaxors/piezoelectrics.

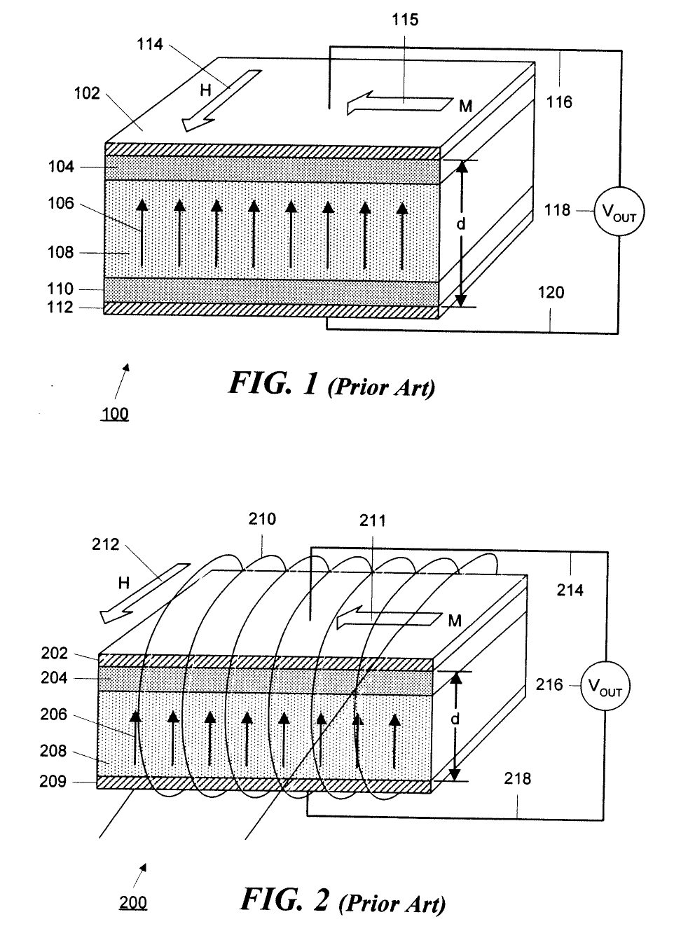

TABLE 1

| | | | max. | Sensitivity | |
|---|---|---|---|---|---|
| | gᵢⱼ | l | stress | Calc. | Obs. |
| Piezo/magnetic sensors: | | | | | |
| FIG. 1 d₃₁ sensor | 11 | 10⁻³ | 10⁸ | 10⁴ | 280 |
| FIG. 2 d₃₁ sensor | 11 | 10⁻³ | 10⁸ | 10⁴ | 1,200 |
| Inventive d₃₃ sensor | 24 | 10⁻² | 10⁹ | 2 × 10⁵ | 1.5 × 10⁴ |
| Relaxor/magnetic sensors: | | | | | |
| Inventive d₃₃ relaxor/mag sensor | 60 | 10⁻² | 10⁹ | 10⁶ | (10⁵) |

The calculated sensitivity in the table is defined with f=1 in MKS units (V/Tesla) as

$$\frac{\partial V}{{μ}_{o} \partial H} \approx {g}_{33}^{piezo} l \frac{{B}_{1}}{{μ}_{o} {H}_{a}}$$

Here B₁ is the magnetoelastic coupling coefficient, a material constant that generates the magnetic stress in the magnetostrictive material, σₘ, which was used in earlier equations.

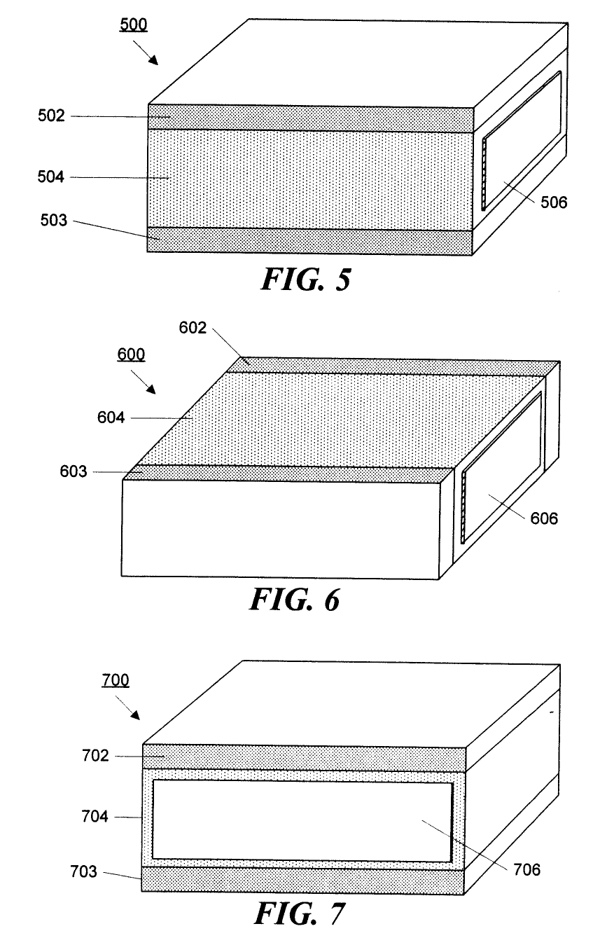

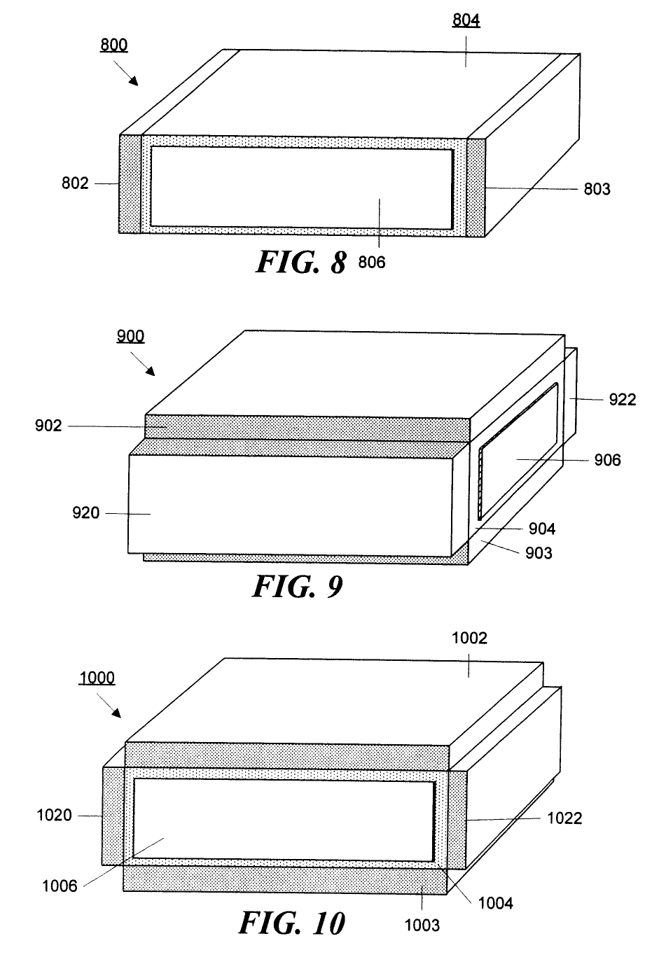

Various embodiments of the sensor illustrated in FIG. 4 are shown in FIGS. 5-12. In these embodiments, the electroactive layer is a rectangular prism having thickness, t, width, w, and length, l, with t≦w≦l and three pairs of opposing faces. The electrodes are placed on one pair of opposing faces and the magnetostrictive layers are bonded to one or more pairs of opposing faces. In these figures, the wires connected to the electrodes have been omitted for clarity. For example, in the embodiment 500 illustrated in FIG. 5, two magnetostrictive layers 502 and 503 are bonded to the top and bottom faces (w×l) of the rectangular prism 504. In general, in embodiments in which two magnetostrictive layers are mounted on opposing faces of the electroactive layer, the magnetostrictive layers are annealed or otherwise constructed so that the quiescent magnetization vectors in the layers are in opposing directions. This maximizes the stress applied to the electroactive layer. The electrodes, of which electrode 506 is illustrated are attached to the end faces (w×t). In the embodiment 600 shown in FIG. 6, two magnetostrictive layers 602 and 603 are bonded to the side faces (l×t) of the rectangular prism 604. The electrodes, of which electrode 606 is illustrated, are attached to the end faces (w×t). In the embodiment 700 shown in FIG. 7, two magnetostrictive layers 702 and 703 are bonded to the top and bottom faces (w×l) of the rectangular prism 704. The electrodes, of which electrode 706 is illustrated are attached to the side faces (t×l). In still another embodiment 800 shown in FIG. 8, two magnetostrictive layers 802 and 803 are bonded to the end faces (w×t) of the rectangular prism 804. The electrodes, of which electrode 806 is illustrated are attached to the side faces (t×l).

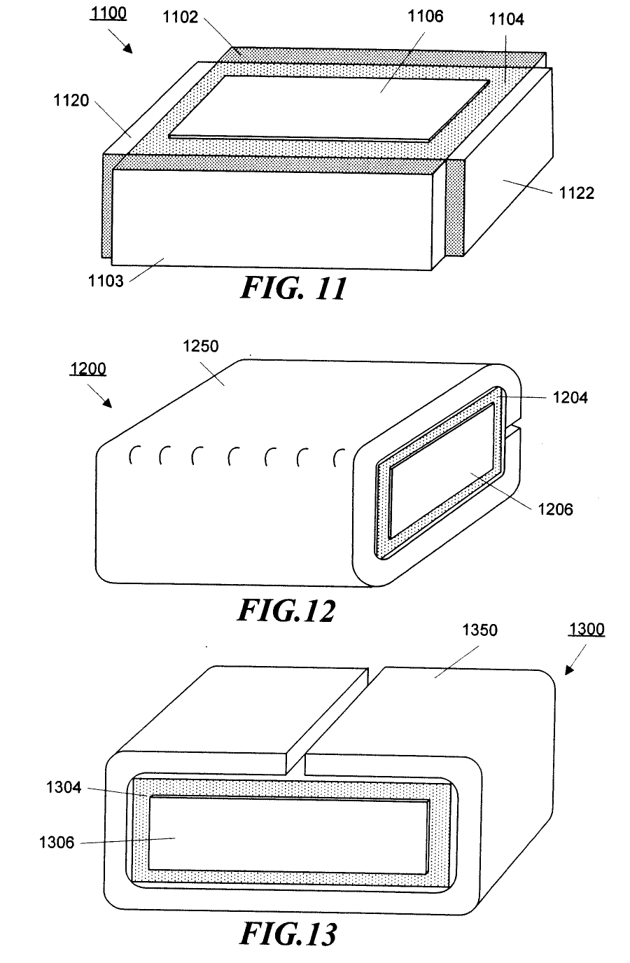

FIGS. 9-11 illustrate embodiments in which four magnetostrictive layers are bonded to two pairs of opposing faces. In these embodiments, the electroactive layer is a rectangular prism having thickness, t, width, w, and length, l, with t≦w≦l and three pairs of opposing faces. The electrodes are placed on one pair of opposing faces and the magnetostrictive layers are bonded to one or more pairs of opposing faces. In these figures, the wires connected to the electrodes have been omitted for clarity. For example, in the embodiment 900 illustrated in FIG. 9, two magnetostrictive layers 902 and 903 are bonded to the top and bottom faces (w×l) of the rectangular prism 904. An additional two magnetostrictive layers 920 and 922 are bonded to the side faces (l×t) of the rectangular prism 904. The electrodes, of which electrode 906 is illustrated are attached to the end faces (w×t). In the embodiment 1000 shown in FIG. 10, two magnetostrictive layers 1002 and 1003 are bonded to the top and bottom faces (w×l) of the rectangular prism 1004. An additional two magnetostrictive layers 1020 and 1022 are bonded to the end faces (w×t) of the rectangular prism 1004. The electrodes, of which electrode 1006 is illustrated, are attached to the side faces (l×t). In the embodiment 1100 shown in FIG. 11, two magnetostrictive layers 1102 and 1103 are bonded to the side faces (l×t) of the rectangular prism 1104. An additional two magnetostrictive layers are bonded to the end faces (w×t) of the prism 1104. The electrodes, of which electrode 1106 is illustrated are attached to the top and bottom faces (w×l).

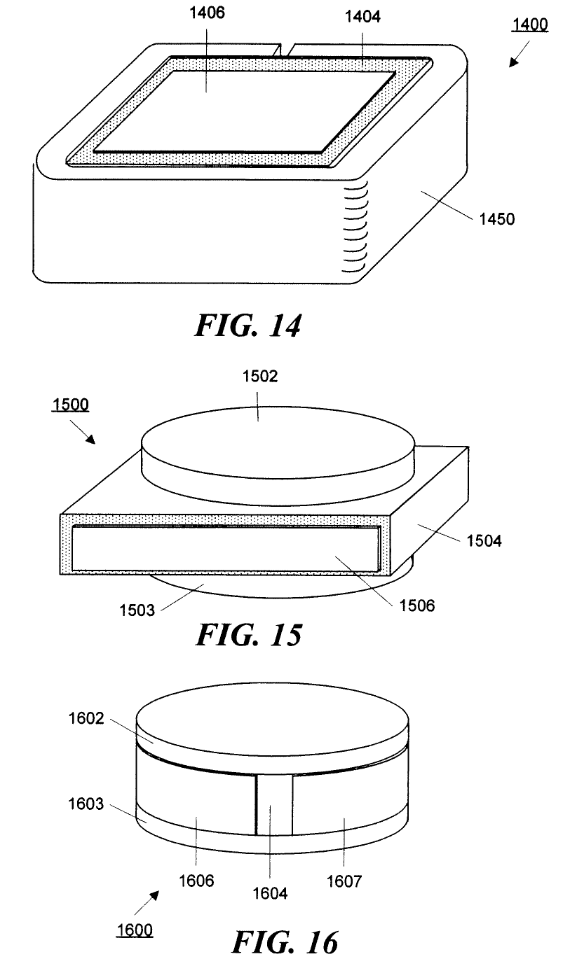

FIGS. 12-14 illustrate embodiments in which a single piece of magnetostrictive material is wrapped around, and bonded to, a rectangular prism of electroactive material. In these embodiments, the electroactive layer is a rectangular prism having thickness, t, width, w, and length, l, with t≦w≦l and three pairs of opposing faces. The electrodes are placed on one pair of opposing faces and the magnetostrictive layer is wrapped around and bonded to one or more pairs of opposing faces. In these figures, the wires connected to the electrodes have been omitted for clarity. For example, in the embodiment 1200 illustrated in FIG. 12, the magnetostrictive layer 1250 is wrapped around and bonded to the top and bottom faces (w×l) and the side faces (l×t) of the rectangular prism 1204. The electrodes, of which electrode 1206 is illustrated are attached to the end faces (w×t). In the embodiment 1300, shown in FIG. 13, the magnetostrictive layer 1350 is wrapped around and bonded to the top and bottom faces (w×l) and the end faces (w×t) of the rectangular prism 1304. The electrodes, of which electrode 1306 is illustrated, are attached to the side faces (l×t). In the embodiment 1400 shown in FIG. 14, the magnetostrictive layer 1450 is bonded to the side faces (l×t) and the end faces (w×t) of the prism 1404. The electrodes, of which electrode 1406 is illustrated are attached to the top and bottom faces (w×l).

FIGS. 15-17 illustrate embodiments in which the magnetostrictive layer is disk-shaped with a circular, or elliptical, cross-section. These embodiments have the advantage that the magnetostrictive layer easily responds to an external magnetic field applied in any in-plane direction. The embodiment illustrated in FIG. 15 the electroactive layer is a rectangular prism having thickness, t, width, w, and length, l, with t≦w≦l. Disk-shaped magnetostrictive layers 1502 and 1503 are bonded to the top and bottom faces (w×l) of the rectangular prism 1504. The electrodes, of which electrode 1506 is illustrated in FIG. 15, are attached to the ends (w×t) of the prism 1504.

FIG. 16 illustrates an embodiment 1600 in which the electroactive layer 1604 is also disk-shaped with a circular, or elliptical, cross section. The electroactive layer has a diameter, d, and a thickness, t, with d>t. Disk-shaped magnetostrictive layers 1602 and 1603 are bonded to the top and bottom faces of the disk 1604. The electrodes 1606 and 1607 are attached to the side wall of the disk 1604.

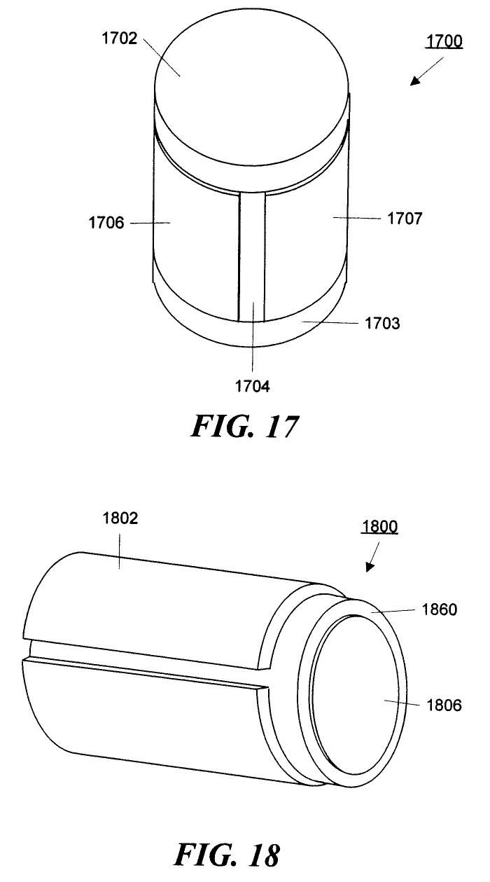

FIG. 17 illustrates an embodiment 1600 in which the electroactive layer 1504 is cylindrically shaped with a circular, or elliptical, cross section. The electroactive layer has a diameter, d, and a thickness, t, with d<t. Disk-shaped magnetostrictive layers 1702 and 1703 are bonded to the top and bottom faces of the cylinder 1704. The electrodes 1706 and 1707 are attached to the side wall of the cylinder 1704.

FIGS. 18-20 illustrate embodiments in which the electroactive material is either a solid cylinder or a hollow cylinder with a layer of magnetostrictive material bonded thereto and electrodes applied accordingly. For example, the embodiment 1800 shown in FIG. 18 utilizes a solid cylinder 1860 of electroactive material with one or more layers 1802 of magnetostrictive material wrapped around and bonded to the outer surface of the cylinder 1860. In this embodiment, the electrodes, of which electrode 1806 is shown in FIG. 18, are attached to the ends of the cylinder.

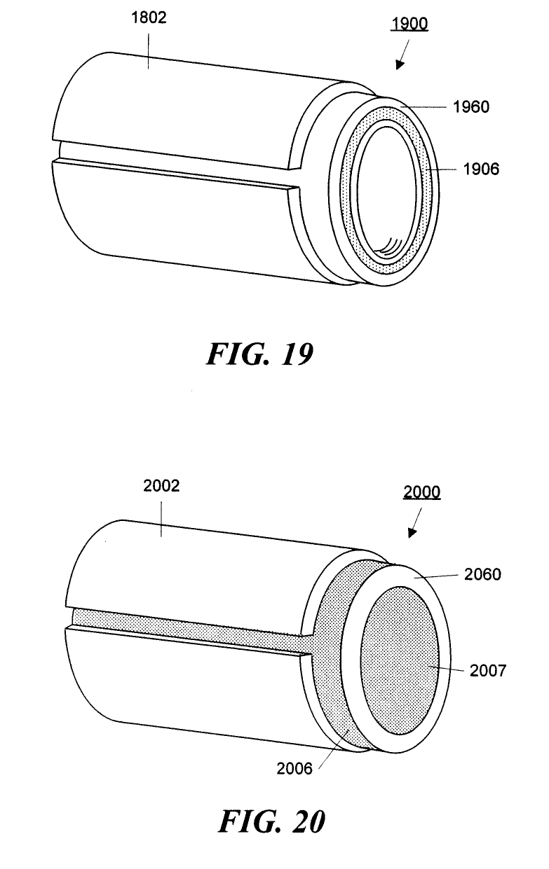

FIG. 19 shows an embodiment 1900 similar to that of FIG. 18 with the exception that the cylinder 1960 of electroactive material is hollow and ring-shaped electrodes (of which electrode 1906 is shown in FIG. 19) are applied to the ends of the cylinder.

FIG. 20 shows another embodiment 2000 that is similar to that shown in FIG. 19 with the exception that the electrodes 2006 and 2007 are applied to the inner and outer surfaces of the electroactive material cylinder 2060. Instead of, or in addition to, one or more layers of magnetostrictive material being wrapped around, and bonded to, the outside of cylinder 2060, additional embodiments may have either a solid cylinder of magnetostrictive material or a curled layer of magnetostrictive material inserted into the hollow interior of cylinder 2060. In this embodiment expansion of the magnetostrictive material along the axis of the cylinder generates a Poisson stress that reduces the cylinder thickness and changes the polarization of the electroactive material. In the case where an electrically conductive magnetostrictive material is wrapped around the outside of cylinder 2060, the outer electrode can be eliminated and the magnetostrictive material can be bonded to the electroactive material with a conductive material, such as a conductive epoxy. In this latter embodiment, the magnetostrictive layer serves as the outer electrode.

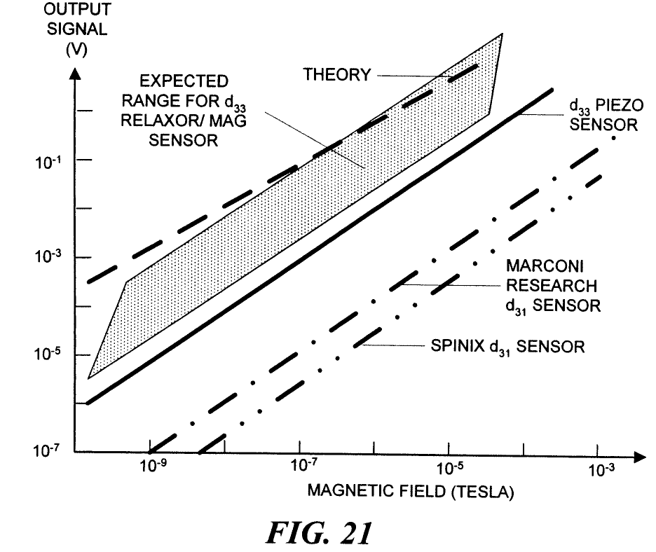

FIG. 21 is a comparison of the output voltage signal vs. magnetic field strength and summarizes the results for the sensors listed in Table 1. For the sensor of the present invention, results for an electroactive layer of PZT piezoelectric material are shown as well as the range of values expected for such a sensor using a relaxor ferroelectric material for the electroactive element.

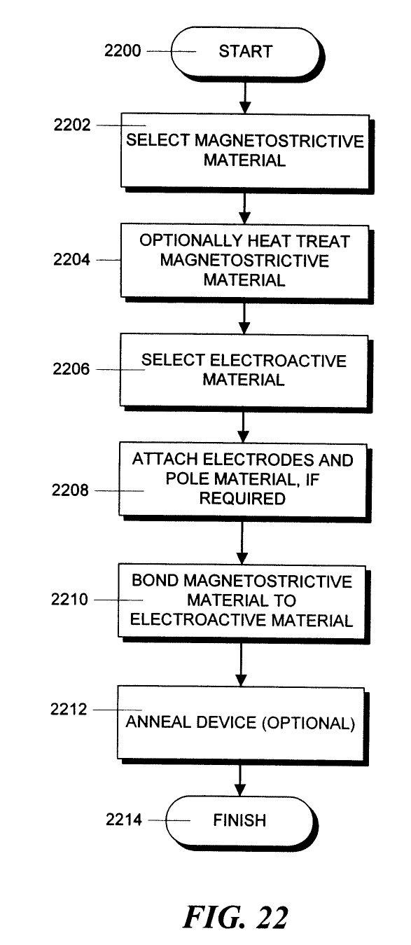

FIG. 22 shows the steps in an illustrative method for constructing the inventive device. The process begins in step 2200 and proceeds to step 2202 where a suitable magnetostrictive material is selected from the known magnetostrictive materials discussed above. In step 2204, the magnetic material may be heat treated with or without an applied magnetic field, to simply relieve internal stress, or to relieve stress and induce a preferred, quiescent direction of magnetization, respectively. Next, in step 2206, a suitable electroactive material is selected from among the electroactive materials discussed above. The electroactive material may already have electrodes applied, if not, they can be added in step 2208. The electrodes are used to polarize the electroactive material if it is a piezoelectric, and are needed on any electroactive material to detect the output voltage. In order to pole the piezoelectric material, a voltage with sufficient magnitude to saturate the material is applied to the electrodes in a known manner. In step 2210, the magnetostrictive material is bonded to the electroactive material by using a glue or suitable adhesive. Next, in step 2212, the entire device may then be subjected to a stress relief annealing, and, if not done in an earlier step, a field may be applied during this annealing if it is necessary to adjust the quiescent direction of magnetization. The process then finishes in step 2214.

The devices of the present invention are versatile because the output voltage and current can be varied (while their product remains approximately constant) by choosing the electrode spacing and electroactive element dimensions appropriately. The use of the d₃₃ mode of an electroactive element offers a clear improvement over the d₃₁ mode of the prior art piezoelectric based devices. Further, the extension of the choice of electroactive elements to relaxor ferroelectrics and electroactive polymers offers further enhancements in output. The choice of the magnetic element allows the performance of the field sensor to be tailored to the field range to be measured.

Because of the increased output voltage of the sensors of the present invention, it is expected that they could replace the magnetic/piezoelectric devices of the prior art and will also open new applications not yet accessible to sensors of the prior art. Particularly, new applications are expected in mine detection, ship detection—including antisubmarine warfare (ASW), geophysical exploration, linear and rotational motion detection, data reading from credit cards, tapes and other magnetic information storage media, electric, gas, water and other meter readers, antilock braking systems, etc. Because the sensor can be configured to be sensitive to stress as well as magnetic field, it is also likely that the new sensors of the present invention will open totally new applications in energy harvesting. This dual-sensing capability (stress and magnetic field) could also expand the utility and reliability of the sensor in the ASW area, detecting both magnetic and acoustic signatures of nearby vessels. This dual sensing capability could also make these sensors useful in detecting personnel and vehicle movement in urban environments as well as on the battlefield or in remote or inaccessible areas. In all these applications, the sensor remains essentially passive, requiring no input power to sense magnetic fields or accelerations. Further, in environments with vibrations above the 0.01 g level and with frequency components above about 15 Hz, the energy harvesting capability could allow the self-powered transmission of data from the passive detector.

Although an exemplary embodiment of the invention has been disclosed, it will be apparent to those skilled in the art that various changes and modifications can be made which will achieve all or some of the advantages of the invention without departing from the spirit and scope of the invention. For example, it will be obvious to those reasonably skilled in the art that, in other implementations, other known materials different from those listed may be used. Other aspects, such as the specific process flow and the order of the illustrated steps, as well as other modifications to the inventive concept are intended to be covered by the appended claims. Although the invented device provides a significant increase in output voltage in its passive mode of operation compared to many state-of-the-art sensors, further increases in sensitivity can be achieved by the use of an AC bias field (which reduces noise and drift in the measurement process).

What is claimed is:

1. A magnetic field sensor for sensing an applied magnetic field, the sensor comprising:
a layer of magnetostrictive material having a magnetization vector that responds to the applied magnetic field by rotating in a plane and generating a stress;
a layer of electroactive material, mechanically bonded to the layer of magnetostrictive material, that responds to the stress by generating a voltage; and
electrodes that measure the voltage generated by the electroactive material in a direction substantially parallel to the plane in which the magnetization vector rotates.

2. The sensor of claim 1 wherein the magnetostrictive material is selected from the group consisting of amorphous-FeBSi, FeCoBSi alloys, polycrystalline nickel, iron-nickel alloys, iron-cobalt alloys and TbDyFe alloys.

3. The sensor of claim 2 wherein the magnetostrictive material is selected from the group consisting of FeₓB_{y}Si_{1-x-y}, where 70<x<86 at %, 2<y<20, and 0<z=1−x−y<8 at %, FeₓCo_{y}B_{z}Si_{1-x-y-z} where 70<x+y<86 at % and y is between 1 and 46 at %, 2<z<18, and 0<1−x−y−z<16 at %, polycrystalline nickel, iron-nickel alloys where Ni is between 40 and 70 at %, iron-cobalt alloys where Co between 30 and 80%, and alloys.

4. The sensor of claim 2 wherein the magnetostrictive material comprises a composition near Fe₇₈B₂₀Si₂.

5. The sensor of claim 2 wherein the magnetostrictive material comprises a composition near Fe₆₈Co₁₀B₁₈Si₄.

6. The sensor of claim 2 wherein the magnetostrictive material comprises an iron-nickel alloy with substantially 50% Ni.

7. The sensor of claim 2 wherein the magnetostrictive material comprises an iron-cobalt alloy with substantially 55% Co.

8. The sensor of claim 1 wherein the electroactive material is selected from the group consisting of lead zirconate titanate ceramics (Pb(ZrₓTi₁₋ₓ)O₃), polyvinylidene difluoride polarized polymers (PVDF), aluminum nitride (AIN), quartz (SiOₓ), ferroelectric materials, electrostrictive materials and relaxor ferroelectric materials.

9. The sensor of claim 8 wherein the electroactive material is electrostrictive material substantial of the form (Bi_{0.5}Na_{0.5})₁₋ₓBaₓZr_{y}Ti_{1-y}O₃).

10. The sensor of claim 8 wherein the electroactive material is a relaxor ferroelectric material substantially of the form Pb(Mg_{1/3}Nb_{2/3})₃O₃).

11. The sensor of claim 1 wherein the magnetostrictive layer is bonded to the electroactive layer with non-conductive glue.

12. The sensor of claim 11 wherein the glue is non-conductive epoxy.

13. The sensor of claim 1 wherein the electroactive layer is a rectangular prism having thickness, t, width, w, and length, l, with t≦w≦l and three pairs of opposing faces and wherein the electrodes are on one pair of opposing faces and the magnetostrictive layer and a second magnetostrictive layer are bonded to another pair of opposing faces.

14. The sensor of claim 13 wherein a third and a fourth magnetostrictive layers are bonded to the third pair of opposing faces.

15. The sensor of claim 14 wherein the magnetostrictive layer is a continuous piece wrapped around and bonded to two pairs of opposing sides and the electrodes are on a third pair of opposing sides.

16. The sensor of claim 1 wherein the magnetostrictive layer is disk-shaped

17. The sensor of claim 1, wherein the electroactive layer is a cylinder with two circular faces and a side wall, the magnetostrictive layer is bonded to at least one circular face and electrodes are on the side wall in an opposing relationship.

18. The sensor of claim 17 wherein the side wall has a circumference and wherein the electrodes are arc-shaped, each electrode having an arc length of at least ⅛ and not greater than ⅜ of the circumference of the side wall.

19. The sensor of claim 1 wherein the electroactive layer is a cylinder of thickness, t, and diameter, d, and wherein t≧d.

20. The sensor of claim 1 wherein the electroactive layer is a cylinder with two circular faces of diameter d and a side wall of height h wherein h≧d and wherein the electrodes are on the circular faces and the magnetostrictive layer is bonded to the side wall.

21. The sensor of claim 1, wherein the electroactive layer forms a hollow cylinder of length l, thickness t, and diameter, d where t<d/2 and t≦l and a pair of opposing end faces.

22. The sensor of claim 21 wherein the electrodes are applied to an inner cylinder surface and an outer cylinder surface.

23. The sensor of claim 22 wherein the magnetostrictive layer comprises a cylinder of magnetostrictive material inserted into the hollow cylinder of electroactive material.

24. The sensor of claim 21 wherein the electrodes are applied to the opposing end faces.

25. The sensor of claim 21 wherein the magnetostrictive material layer comprises a single piece of magnetostrictive material wrapped over, and bonded to, an outer surface of the cylinder.

26. The sensor of claim 21 wherein the magnetostrictive material layer comprises a single piece of magnetostrictive material wrapped over, and bonded to, an inner surface of the cylinder.

27. A magnetic field sensor for sensing an external magnetic field, the sensor comprising:
a layer of magnetostrictive material having a magnetization vector that responds to the applied magnetic field by rotating in a plane and generating a stress;
a layer of electroactive material mechanically bonded to the layer of magnetostrictive material that responds to the stress by generating a voltage; and
means for measuring the voltage generated by the electroactive material in a direction substantially parallel to the plane in which the magnetization vector rotates.

28. The sensor of claim 27 wherein the electroactive layer is a rectangular prism having thickness, t, width, w, and length, l, with t≦w≦l and three pairs of opposing faces and wherein the electrodes are on one pair of opposing faces and the magnetostrictive layer and a second magnetostrictive layer are bonded to another pair of opposing faces.

29. The sensor of claim 27 wherein the magnetostrictive layer forms a hollow cylinder with an axis and a surface and the magnetostrictive layer has a magnetization vector that changes orientation from circumferential to axial on the surface of the cylinder in response to an external magnetic field applied in a direction parallel to the axis.

30. The sensor of claim 27 wherein the electroactive layer forms a hollow cylinder with an axis and a surface and wherein the magnetostrictive layer is wrapped around and bonded to the surface and has a magnetization vector that changes orientation from circumferential to axial on the surface of the cylinder in response to an external magnetic field applied in a direction parallel to the axis.

31. The sensor of claim 30 further comprising a second magnetostrictive layer bonded to an inner surface of the hollow cylinder, wherein the second magnetostrictive layer has a magnetization vector that changes orientation from circumferential to axial on the surface of the cylinder in response to an external magnetic field applied in a direction parallel to the axis.

32-42. (canceled)

43. An apparatus that responds to an external magnetic field, the apparatus comprising:
a layer of magnetostrictive material having a magnetization vector that responds to the magnetic field by rotating in response to the magnetic field and generating a magnetostrictive stress in a direction;
a layer of electroactive material, mechanically bonded to the layer of magnetostrictive material, that responds to the magnetostrictive stress by generating a voltage; and
electrodes across which appears the voltage generated by the electroactive material in a direction substantially parallel to the direction in which the principal magnetostrictive stress is generated.

44. The apparatus of claim 43 wherein the magnetostrictive material is selected from the group consisting of amorphous-FeBSi, FeCoBSi alloys, polycrystalline nickel, iron-nickel alloys, iron-cobalt alloys and TbDyFe alloys.

45. The apparatus of claim 43 wherein the electroactive layer is a rectangular prism having three pairs of opposing faces and wherein the electrodes are on one pair of opposing faces and the magnetostrictive layer is bonded to one face of another pair of opposing faces.

46. The apparatus of claim 45 further comprising a second magnetostrictive layer bonded to another face of the other pair of opposing faces.

47. The apparatus of claim 45 wherein the magnetostrictive layer is a continuous piece wrapped around and bonded to two pairs of opposing sides and the electrodes are on a third pair of opposing sides.

48. The apparatus of claim 43 wherein the magnetostrictive layer is disk-shaped

49. The apparatus of claim 43, wherein the electroactive layer is a cylinder with two circular faces and a side wall, the magnetostrictive layer is bonded to at least one circular face and electrodes are on the side wall in an opposing relationship.
